(19) United States
(12) Patent Application Publication
(10) Pub. No.: US 2016/0007503 A1
(43) Pub. Date: Jan. 7, 2016

(54) MOUNTING FRAMEWORK FOR ARRANGING ELECTRONIC COMPONENTS

(71) Applicant: ZAKRITOE AKZLONEMOE OBSHESTVO "RSK TECHNOLOGIES", Moscow (RU)

(72) Inventors: Egor A Druzhinin, Moscow (RU); Andrey A. Mihasev, Moscow (RU); Alexey B Shmelev, Moscow (RU)

(73) Assignee: Zakritoe Akzionernoe obshestvo "RSK Technologies", Moscow (RU)

(21) Appl. No.: 14/443,384

(22) PCT Filed: Feb. 4, 2014
(86) PCT No.: PCT/RU2014/000080

§ 371 Date: May 17, 2015

(30) Foreign Application Priority Data
Mar. 26, 2013 (RU) 2013113186

(51) Int. Cl. H05K 7/20

(52) U.S. Cl. CPC H05K 7/20272

(57) ABSTRACT

A mounting frame for arrangement of electronic components includes a set of horizontal shelves and vertical posts of the frame with, at least, one internal channel for coolant to pass therethrough, forming coolant feed channel and coolant drain channel. The mounting frame includes at least two horizontal shelves, attached to the horizontal shelves of the frame, and at least one an electronic component installed thereon. One of the horizontal shelf includes at least one flexible hose, connected to the coolant feed channel to connect the coolant feed channel to it of at least one electronic component. The adjacent horizontal shelf includes at least one flexible hose connected with coolant drain channel, so that to link it with own coolant drain channel of, at least, one electronic component, inlet opening for feeding the coolant into coolant feed channel, and outlet opening for removal of coolant from coolant drain channel.

Claimed utility model applies to electronics, in particular to the units for installation and cooling of power units of computer computation modules, network devices and storage system and more particularly to the systems and methods for cooling without air circulation.

The most relevant prior art is Russian Federation Patent No. RU2088059C1 issued Aug. 8, 1997, where the cabinet includes a set of horizontal and vertical posts of the cabinet, at least two horizontal shelves and/or walls, attached to the vertical posts of the cabinet with, at least, one internal channel for coolant to pass through and, at least, one electronic component installed on it, inlet and outlet for coolant feed, coolant feed and coolant drain channels, connected correspondingly with inlet and outlet.

The shortcoming of the mentioned cabinet: it is not possible to install electronic components with inhomogeneous heat generation in its structure, those equipped with their own liquid coolers of different configuration. Dissipated power of integrated circuits, devices with integrated circuits, is increasing. This tendency calls for optimization of cooling systems both on modular and system level. Normally higher air stream volume is needed for efficient cooling of high power modules and higher temperature of the air coming out of the modules being cooled. As a rule, many units, such as computation modules, as well as corresponding electronics (for example, processors, memory, hard disks, network devices, power units, amplifiers, etc.) are on board of the removable structure or combined within the bin or chassis.

Normally, components are cooled with air moving in parallel directions, as a rule, front-to-back, driven by one or several units (for example, by fans). Increasing heat power within one body or chassis can be compensated by provision of higher air stream, for example, by means of more powerful fan or by means of higher speed of rotation.

However, this approach tends to be inapplicable in the context of big data processing centers. Applicable thermal conditions are ensured by higher scope of air, moving in the room. It may happen that hot air coming out of certain equipment approaches the inlet of the adjacent ones. Moreover, the level of acoustic noise from the air moving from massive body or chassis can be within acceptable limits, then total acoustic noise in the room can go beyond acceptable level. Moreover, air ducts in bodies have limited space, which makes it impossible to optimize aerodynamics and acoustics of inlet and outlet of airstreams. Besides, as a result of unoptimised airstream passing vibration is generated. The level of this vibration keeps on increasing due to interference in electronic boards placed nearby.

Accordingly, it is very important to strengthen cooling mechanisms of electronic components as well as the components themselves, individually and on all levels of installation, including blades, body or wiring cabinet. Necessity to cool the existing and future high heat load from electronic components calls for development of new systems of cooling, such as liquid systems of cooling and production methods for wiring cabinets. Wiring cabinet with the system of distribution of liquid coolant for installation of electronic components with unhomogeneous heat generation, equipped with liquid coolants, described here, is needed to develop the systems of liquid-type cooling for electronic devices and so that to make cooling of multi-component electronic systems easier, such as posts, including several types of different electronics or blades. Wiring cabinet fully substitutes some bodies of electronic units and makes it possible to install electronic components with unhomogeneous heat generation in its structure, equipped with liquid-type coolants of different configuration. This is justified for installation of the component both in one horizontal level and in several ones.

Technical result of the technical solution being proposed is higher effectiveness and efficiency of the design of computer electronic modules cooling system, simplification of their design and improvement of reliability features, reduction of energy consumption of the cooling system in general.

Mentioned technical result is achieved by the fact that the cabinet where electronic components are to be installed includes: a set of horizontal cross bars and vertical posts of the frame with, at least, one internal channel for coolant passing, forming coolant feed channel and coolant drain channel, at least two horizontal shelves, attached to horizontal cross bars of the frame, and at least one electronic component installed on them. One horizontal cross bar includes, at least, one flexible hose, linked to coolant feed channel so that to connect it with own coolant feed channel of at least one electronic component,

Adjacent horizontal cross bar includes, at least, one flexible hose, linked to coolant drain channel, so that to connect it with own coolant drain channel of, at least, one electronic component, inlet opening for feeding coolant into coolant feed channel, and outlet opening for taking coolant out of coolant drain channel

Besides, in every horizontal shelf there can be at least one internal channel for coolant to pass through, and flexible hoses for feed and drain of coolant can be connected to the inlet and outlet of it. Odd horizontal cross bar of the cabinet and vertical posts of one side of the cabinet form coolant feed channel, and four horizontal cross bars of the cabinet and vertical posts of the other side of the cabinet form coolant drain channel or vice versa.

For efficient performance of the cabinet cooled coolant is supplied to inlet opening, and outlet opening serves for removal of warm coolant, besides it is preferred to connect the pump feeding coolant from external tank with coolant, where coolant is cooled efficiently, to inlet opening by means of a valve. Besides, it is preferred that the ends of flexible hoses have fittings john guest or the valve with john guest fitting. In principle, all channels of the cabinet can be made by arranging flexible hoses in horizontal and vertical posts of the cabinet and joined by john guest fittings or the valves with john guest fittings, making separate coolant feed and drain channels. The proposed cabinet for installation of electronic components can be installed and gets fixed in any external cabinet and it can be used as power element taking weight from the side of at least one electronic component.

The proposed utility model is explained by the following figures.

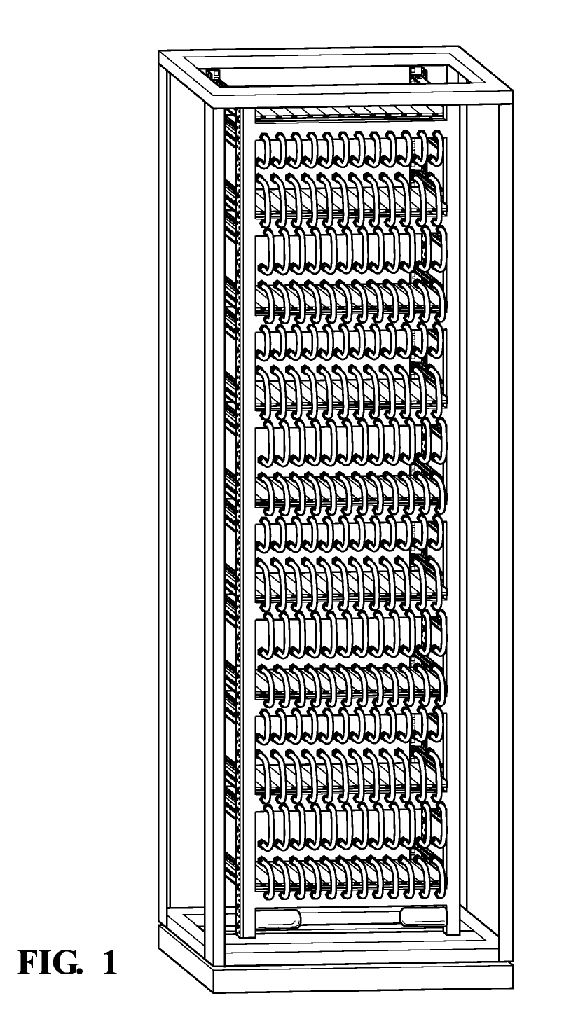

FIG. 1 is a general view of the cabinet for installation of electronic components;

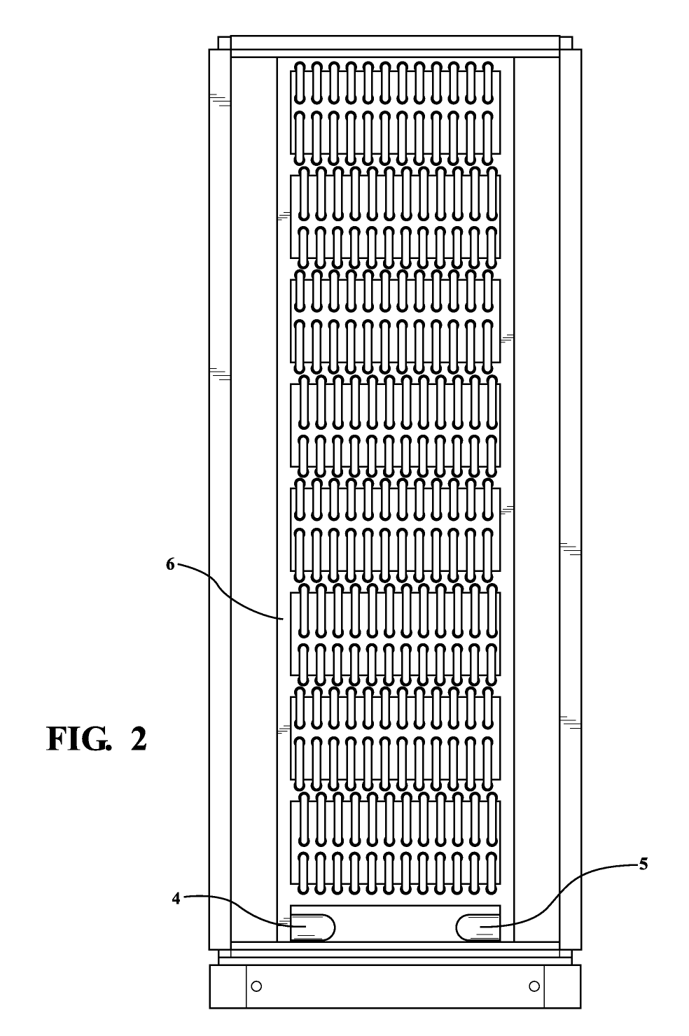

FIG. 2 is a scheme of coolant flows inside the cabinet; and

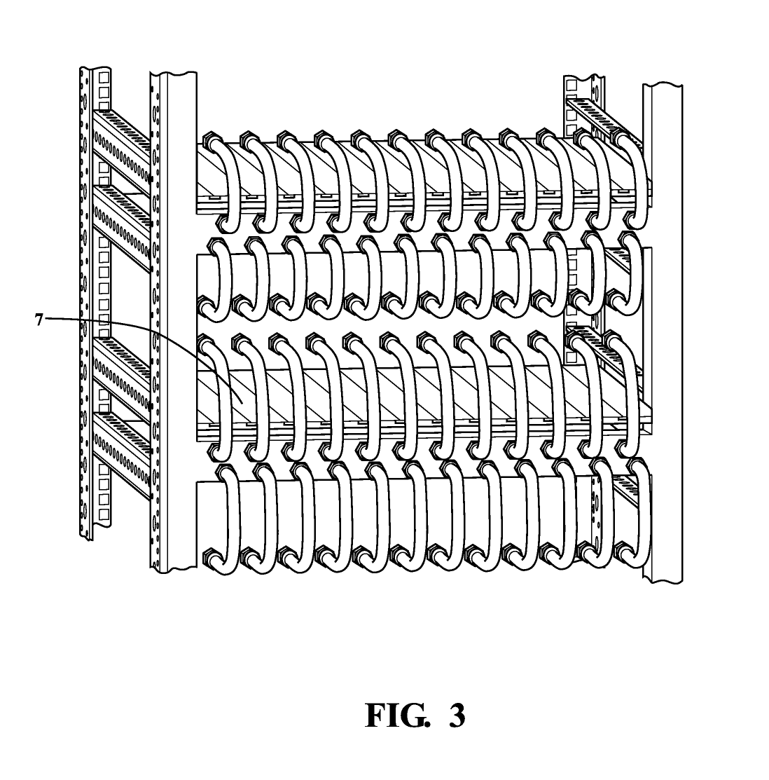

FIG. 3 is an example of connection of flexible hoses with coolant drain/ feed channels.

Proposed technical solution: formation of the structure of wiring cabinet with the system of distribution of liquid coolant in the form of one assembly which fully replaces individual bodies of electronic units and makes it possible to install electronic components with inhomogeneous heat generation in its structure, equipped with liquid coolants of different configuration FIG. 1. The construction includes a wiring cabinet structure, a liquid coolant distribution system for installation to one of the front, and/or back and/or lateral wall of wiring cabinet, which includes structures for installation of electronic components with unhomogeneous heat generation, equipped with liquid coolants of different configuration. The liquid coolant distribution system includes coolant feed channel and coolant drain channel, meant to ensure cooling of at least one electronic module equipped with liquid coolant, the system includes at least one inlet 4 as shown on FIG. 2 and outlet openings 5, connected with the channel 6 to feed the coolant.

The system distributing liquid coolant additionally includes a lot of flexible hoses, and each one is connected with coolant feed channel and coolant drain channel of liquid cooling agent of the electronics used in the cabinet. Electronic components with unhomogeneous heat generation of different configuration, equipped with liquid coolants, are installed in guide shelves 7 as shown on FIG. 3 or by means of other ways, for example, fastening tool in shelves 7.

Above, the main peculiarities of the cabinet for installation of electronic components were outlined, but it is obvious for any specialist in this technical field, that it is possible to make variations of the cabinets based on the outlined data, for example with variations of cooling of the proposed and air, etc.

1. (canceled)

2. (canceled)

3. (canceled)

4. (canceled)

5. (canceled)

6. (canceled)

7. A mounting frame for arrangement of electronic components, said mounting frame includes:
a set of horizontal elements and vertical posts and at least one internal channel for coolant to pass therethrough forming coolant feed channel and coolant drain channel;
at least two horizontal shelves, attached to said horizontal elements of the frame, and at least one electronic component installed on said horizontal elements wherein one of said horizontal elements includes at least one flexible hose connected to said coolant feed channel to connect said coolant feed channel to said at least one electronic component; and
adjacent horizontal element includes another flexible hose connected with said coolant drain channel to link it with said coolant drain channel of at least one electronic component, inlet opening for feeding the coolant into said coolant feed channel, and outlet opening for removal of coolant from said coolant drain channel.

8. The mounting frame as set forth in claim 7, wherein in each of said horizontal shelves there is at least one internal channel formed therein for coolant passing through and coolant feed and drain flexible hoses can be connected thereto.

9. The mounting frame as set forth in claim 7, wherein odd horizontal elements of the frame and said vertical posts on one side of the frame form said coolant feed channel, and even horizontal elements of the frame and said vertical posts of the other side of the frame form coolant drain channel or vice versa.

10. The mounting frame as set forth in claim 7, wherein cooled coolant is supplied to said inlet opening for removal of warm coolant.

11. The mounting frame as set forth in claim 7, wherein the ends of said flexible hoses have john guest fitting or a valve with john guest fitting.
